(19) United States
(12) Patent Application Publication
(10) Pub. No.: US 2026/0059735 A1
(43) Pub. Date: Feb. 26, 2026

(54) SYSTEM AND METHODS FOR SUBSTRATE ISOLATION IN VSDRAM

(71) Applicant: Samsung Electronics Co., Ltd., Suwon-si (KR)

(72) Inventor: Wangee KIM, Dublin, CA (US)

(21) Appl. No.: 19/091,810

(22) Filed: Mar. 26, 2025

Related U.S. Application Data
(60) Provisional application No. 63/686,725, filed on Aug. 23, 2024.

(51) Int. Cl. H10B 12/00; H01L 21/762; H10D 62/40; H10D 62/83

(52) U.S. Cl. CPC H10B 12/30; H01L 21/76224; H10D 62/405; H10D 62/83

(57) ABSTRACT

Disclosed herein are methods, devices and systems including a substrate, a first dielectric layer on top of the substrate, a second dielectric layer on top of the first dielectric layer, a first epitaxial semiconductor layer arranged between the first dielectric layer and the second dielectric layer, a second epitaxial semiconductor layer on top of the second semiconductor layer, and a third dielectric layer contacting the first dielectric layer, the second dielectric layer, the first epitaxial semiconductor layer and the second epitaxial semiconductor layer.

### CROSS-REFERENCE TO RELATED APPLICATION

This application claims the priority benefit under 35 U.S.C. § 119(e) of U.S. Provisional Patent Application Ser. No. 63/686,725 filed on Aug. 23, 2024, the disclosure of which is incorporated herein by reference in its entirety.

### TECHNICAL FIELD

The subject matter disclosed herein relates to microelectronics and integrated circuits (IC) structures. More particularly, the subject matter disclosed herein relates to a semiconductor structure having isolation for the substrate.

### BACKGROUND

Semiconductor devices may be created using complex three-dimensional structures made up of sets of smaller components. Such components may include circuit components such as transistors, capacitors, etc. reproduced in large numbers and addressed using a matrix of intersecting lines. However, forming three-dimensional components is complex and may face difficulties in forming both the conductive portions and ensuring sufficient isolation between the individual conductors. It is further noted that background concepts discussed herein are for informational purposes only and are not intended to limit the present disclosure. Nor should the background or field described herein be intended to limit the disclosure herein to a particular use or concept.

### SUMMARY

An example embodiment provides a device including a substrate, a first dielectric layer on top of the substrate, a second dielectric layer on top of the first dielectric layer, a first epitaxial semiconductor layer arranged between the first dielectric layer and the second dielectric layer, a second epitaxial semiconductor layer on top of the second semiconductor layer, and a third dielectric layer contacting the first dielectric layer, the second dielectric layer, the first epitaxial semiconductor layer and the second epitaxial semiconductor layer. In some embodiments, the first dielectric layer and the second dielectric layer may include a nitride. In some embodiments, the third dielectric layer contacts the substrate and extends in a direction orthogonal to the substrate. In some embodiments, the first epitaxial layer may have a thickness of 5-20 nm and the second epitaxial layer may have a thickness of 5-20 nm. In some embodiments, the third dielectric layer may include an oxide. In some embodiments, the first dielectric layer may extend in a direction parallel to the substrate and may extend across the width of the first epitaxial semiconductor layer. In some embodiments, the first epitaxial semiconductor layer, the second epitaxial semiconductor layer, and the substrate may share the same crystalline orientation.

An example embodiment provides a system including a substrate, a first dielectric layer contacting the substrate, a vertical electrode extending in a direction orthogonal from the substrate, with the first dielectric layer between the substrate and the vertical electrode, a first epitaxial semiconductor layer extending in a direction parallel to the substrate and conductively coupled to the vertical electrode, a second dielectric layer on top of the first epitaxial semiconductor layer, a second epitaxial semiconductor layer on top of the second dielectric layer, and the first dielectric layer may isolate the substrate from the vertical electrode. In some embodiments, the first epitaxial semiconductor layer, the second epitaxial semiconductor layer and the substrate may share a common crystalline orientation. In some embodiments, the second dielectric layer may isolate the first epitaxial semiconductor layer from the second epitaxial semiconductor layer, while the second epitaxial semiconductor layer may be conductively coupled to the vertical electrode. In some embodiments, the first dielectric layer and the second dielectric layer may be formed of the same dielectric material. In some embodiments, the first dielectric layer may extend in a direction parallel to the substrate beyond the second dielectric layer.

An example embodiment provides a method including forming a stack on a substate including a first epitaxial semiconductor layer on the substrate and a second epitaxial semiconductor layer on the first epitaxial semiconductor layer, forming a first recess within the first epitaxial semiconductor layer, forming a second recess within the second epitaxial semiconductor layer, depositing a first dielectric material to fill the first recess to form a first dielectric layer, and depositing the first dielectric material to fill the second recess to form a second dielectric layer, and depositing a second dielectric material to extend in a direction orthogonal to the substrate. In some embodiments, the first dielectric layer extends fully between the first epitaxial semiconductor layer and the substrate. In some embodiments, the first epitaxial semiconductor layer and the second epitaxial semiconductor layer are formed of epitaxial silicon sharing the same crystalline orientation as the substrate. In some embodiments, the second dielectric layer may extend partially between the first epitaxial semiconductor layer and the second epitaxial semiconductor layer. In some embodiments, the first dielectric material may be a nitride and the second dielectric material may be an oxide. In some embodiments, the first recess and the second recess may be formed in a direction parallel to the substrate. In some embodiments, the second dielectric material contacts the first epitaxial semiconductor layer and the second epitaxial semiconductor layer.

### BRIEF DESCRIPTION OF THE DRAWING

In the following section, the aspects of the subject matter disclosed herein will be described with reference to example embodiments illustrated in the figures, in which:

FIG. 1 depicts a perspective view of a semiconductor structure according to various embodiments of the subject matter disclosed herein;

FIG. 2A depicts a perspective cross-section view of a semiconductor structure according to various embodiments of the subject matter disclosed herein;

FIG. 2B depicts an enlarged perspective cross-section view of a semiconductor structure according to various embodiments of the subject matter disclosed herein;

FIG. 2C depicts a plan view of a semiconductor structure according to various embodiments of the subject matter disclosed herein;

FIGS. 3A-3I depict cross-section views of an example embodiment of a semiconductor structure at different stages of its manufacture;

FIGS. 4A-4J depict cross-section views of an example embodiment of a semiconductor structure at different stages of its manufacture; and

FIG. 5 depicts a plan view of a method forming a semiconductor structure according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clockwise,” “Three-Dimensional,” etc.) may be interchangeably used with a corresponding non-capitalized version (e.g., “counter clockwise,” “three-dimensional,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Disclosed herein are various embodiments of devices, systems and methods related to a substrate isolation layer within a 3D memory device. A 3D memory device may include one or more layers of devices stacked upon a substrate. A device layer may have one or more of an array of cells, the cells including a pair of electrodes spaced apart by a dielectric, the pair of electrodes forming a capacitor, the capacitor fed by a transistor. One or more vertical electrodes may address the device layers within 3D memory device. A substrate isolation layer may be formed between the cells, the capacitors, the transistors, and the substrate. The substrate isolation layer may be formed from a first dielectric material, the first dielectric material providing electrical, physical, and thermal isolation between the various active elements and the substrate. Upon the substrate isolation layer, the one or more layers of devices include the first dielectric material, a second dielectric material, a semiconductor material and additional conductor and dielectric materials.

The substrate isolation layer and the one or more layers of devices may be formed by a processing including forming an epitaxial stack of liner layers alternating with bulk semiconductor layers on the substrate. The first liner layer may be formed differently than the subsequent liner layers, with the first liner layer having a difference, including one or more of thickness, semiconductor concentration and/or additive concentration. One or more isolation trenches are formed within the epitaxial stack and the substrate, with the isolation trenches in the array area having a central opening, while the isolation trenches on the ends of the array area are closed trenches which are formed without a central opening. The second dielectric material may be deposited within the isolation trenches. A capacitor isolation trench is formed within the central openings and extending between the closed trenches, the capacitor isolation trenches formed by removing portions of the substrate, epitaxial stack, and any intervening layers. The liner layers are then recessed, with differences in the composition resulting in the first liner layer being fully recessed, while the subsequent liner layers are partially recessed to form openings within the epitaxial stack. The bulk semiconductor layers are then thinned to expand the openings formed within the epitaxial stack. Additional amounts of the first dielectric, such as a semiconductor oxide like silicon dioxide, may then be deposited within the openings formed within the epitaxial stack, forming the substrate isolation layer. The capacitor isolation trenches may then be filled with the second dielectric, such as a semiconductor nitride like silicon nitride, to form capacitor isolators, with any excess dielectric being trimmed.

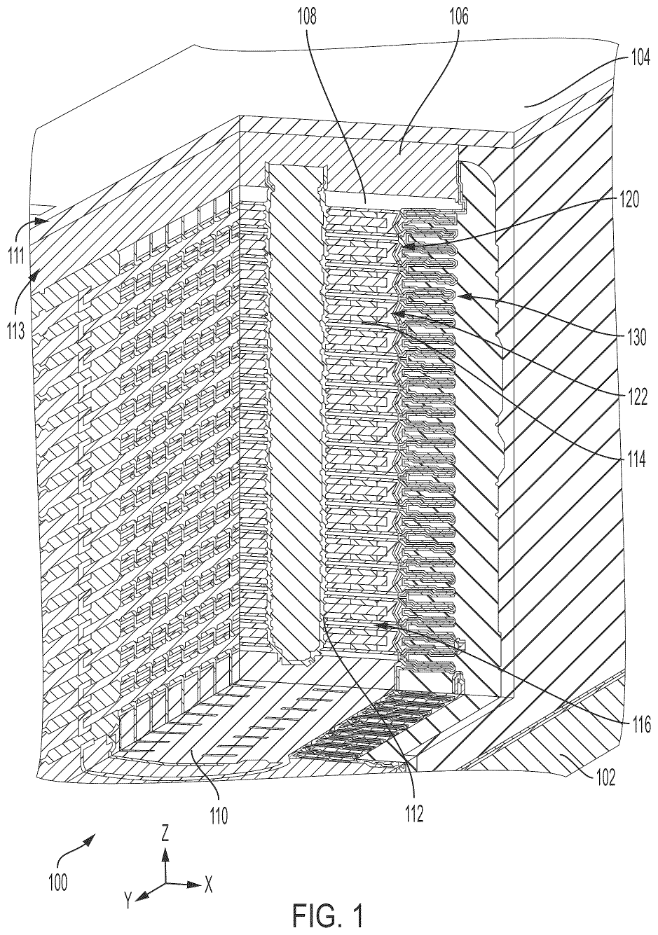

FIG. 1 depicts a perspective view of an example embodiment of a first device architecture 100. The first device architecture 100 may form a portion of a 3D memory device, as well as any other suitable three-dimensional semiconductor devices. In the example of FIG. 1, the 3D memory device may take the form of a vertically stacked device, where individual device layers 120 may be stacked upon each other on a substrate 102. In some embodiments, the substrate 102 may take the form of a semiconductor material, such as silicon, germanium, and may take the form of a die, wafer, other substrates such as an organic substrate or even a silicon on an insulator (SOI) substrate such as glass.

In some embodiments, the individual device layers 120 may take the form of a memory device such as dynamic random-access memory (DRAM), with the resulting 3D memory device of the first device architecture 100 taking the form of a vertically stacked DRAM. However, in other embodiments, the form of the individual device layers 120 may vary, and may include one or more layers such as static random-access memory (SRAM), SDRAM, synchronous dynamic random-access memory (SDRAM), double data rate DRAM or DDR DRAM, flash memory devices, read only memory (ROM), programmable read only memory (PROM), electronically programmable read only memory (EPROM), electronically erasable and programmable read only memory (EEPROM), phase-change random-access memory (Phase-change RAM), ferroelectric random-access memory (FRAM), resistive random-access memory (RRAM) or any other suitable memory devices, either alone or in combination. In the example embodiment of FIG. 1, the individual device layers 120 may be substantially similar to each other, while in other embodiments, the individual device layers 120 may differ from each other.

In the first device architecture 100, the addressing of individual elements such as capacitors, memory cells, or other suitable elements, may be done by use of one or more vertical electrodes 112 and one or more horizontal electrodes 114 to provide signals to one or more capacitors 130. In the example embodiment of FIG. 1, the one or more vertical electrodes 112 extend parallel to the Z-axis, while the one or more horizontal electrodes 114 extend parallel to the Y-axis, and one or more capacitors 130 extend substantially to the X-axis. In some embodiments, each vertical electrode 112 may be used as a bit line and each horizontal electrode 114 may be used as a word line. In other embodiments, each vertical electrode 112 may be used as a word line and each horizontal electrode 114 may be used as a bit line. In some embodiments, the one or more capacitors 130 may be connected to one or more transistors 116, to form one or more memory cells. In some embodiments, the one or more horizontal electrodes 114 may be coupled with one or more transistors 116 prior to the one or more capacitors 130. In some embodiments, within the individual device layers 120, a bulk semiconductor layer 108 may form the one or more transistors 116 and be coupled to the one or more vertical electrodes 112 and the one or more horizontal electrodes 114 to feed each individual memory cells. In some embodiments, the bulk semiconductor layer 108 may be formed primarily from a semiconductor material such as silicon or germanium, and may include additional materials such as dopants and additives like nitrides, carbides, boron, antimony, phosphorus. In some embodiments, the bulk semiconductor layer 108 may be conductive, while in other embodiments, the bulk semiconductor layer 108 may be semiconductive, or non-conductive.

As shown in FIG. 1, and discussed below in more detail, between the one or more vertical electrodes 112 and the substrate 102 is a substrate isolation layer 110. The substrate isolation layer 110 is formed of a first dielectric material 104, which may include semiconductor materials, as well as nitrides, carbides, and oxides thereof, and may consist of silicon nitride, silicon dioxide, or other similar materials such as gallium nitride, gallium oxide, and so forth, and in some embodiments may consistent of a high-k dielectric with a higher dielectric constant (κ) than silicon dioxide, and may include materials such as oxides, silicides and silicates of hafnium and zirconium, such as hafnium silicate, zirconium silicate, hafnium dioxide and zirconium dioxide. The substrate isolation layer 110 may provide a boundary between the one or more vertical electrodes 112 and the substrate 102, with the first dielectric material 104 providing electrical, thermal, and physical protection between the two layers. In some embodiments, the substrate isolation layer 110 may prevent electrical interferences or shorts between the one or more vertical electrodes 112 and the substrate 102. In some embodiments, the substrate isolation layer 110 may also provide for isolation between additional portions of the individual device layers 120 and the substrate 102, such as the one or more horizontal electrodes 114, the one or more transistors 116, the one or more capacitors 130, and the bulk semiconductor layer 108.

The first dielectric material 104 may also be used within the individual device layers 120 including as intralayer dielectrics 122, as well as in forming the substrate isolation layer 110, and a first top isolation layer 111. In some embodiments, the material used as first dielectric material 104 within the substrate isolation layer 110, the first top isolation layer 111, the intralayer dielectrics 122, and the individual device layers 120 may vary, while in other embodiments, the material may be the same or substantially similar.

A second dielectric material 106 may also be used within the first device architecture 100, including within the individual device layers 120, as well a second top isolation layer 113. The second dielectric material 106 may include semiconductor materials, as well as nitrides, carbides, and oxides thereof, and may consist of silicon nitride, silicon dioxide, or other similar materials such as gallium nitride, gallium oxide, and so forth, and in some embodiments may consistent of a high-k dielectric with a higher dielectric constant (κ) than silicon dioxide, and may include materials such as oxides, silicides and silicates of hafnium and zirconium, such as hafnium silicate, zirconium silicate, hafnium dioxide and zirconium dioxide. In some embodiments, the material used as second dielectric material 106 within the second top isolation layer 113 and the individual device layers 120 may vary, while in other embodiments, the material may be the same or substantially similar. In some embodiments, one of the first dielectric material 104 and the second dielectric material 106 may be a nitride, while the other may be an oxide. In some embodiments, when an oxide and nitride are used, the first dielectric material 104 and the second dielectric material 106 may be recessed using a process such as a dry etch or wet etch with the difference in material enabling selective etching of one of the first dielectric material 104 and the second dielectric material 106. In other embodiments, additional chemistries may be included in the first dielectric material 104 and the second dielectric material 106, such as carbides, in addition or as an alternative to oxides and carbides.

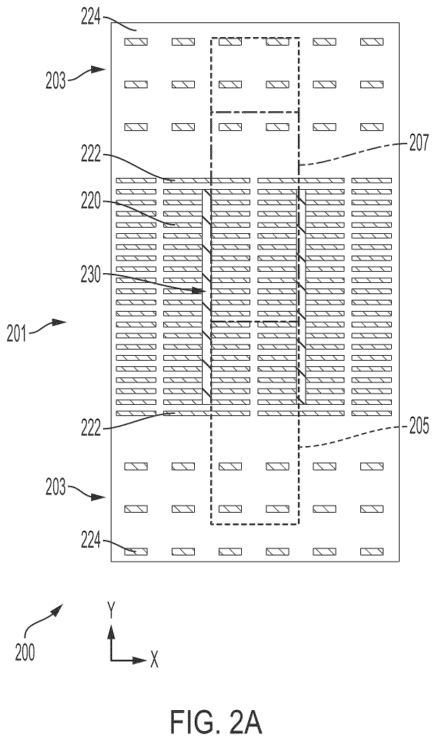

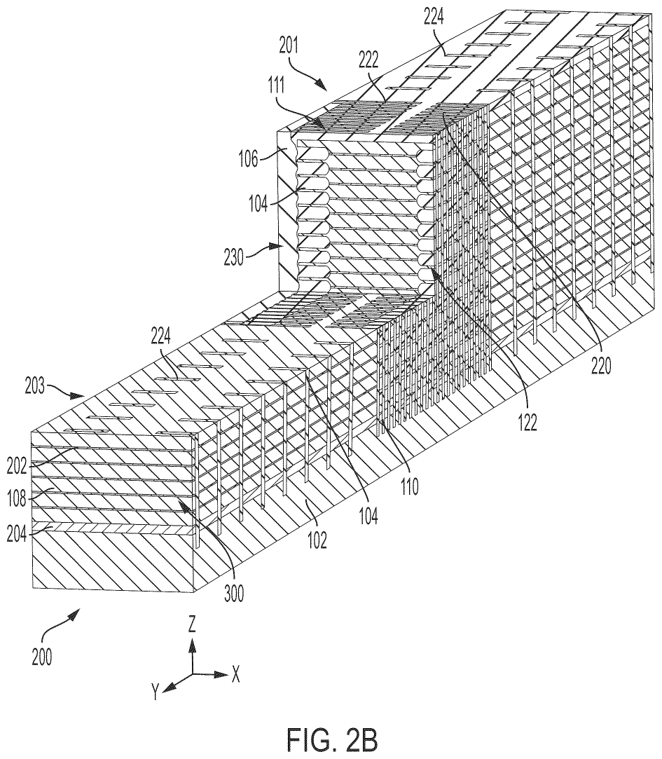

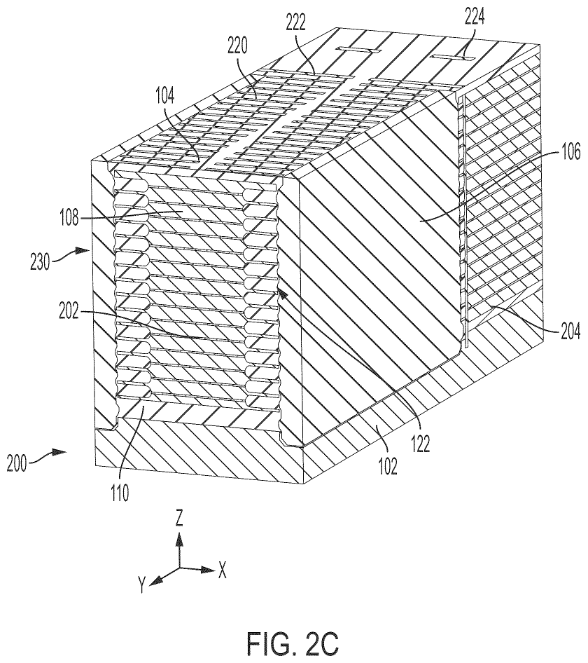

FIG. 2A depicts a plan view of an intermediate structure 200 within the X-Y plane, the intermediate structure 200 being a precursor state to the formation of the first device architecture 100. Within FIG. 2A, there are two types of regions: an array region 201 and a pad region 203. The array region 201, which includes the middle region of FIG. 2A, may correspond to the portions shown in FIG. 1 where the individual device layers 120, including the addressing matrix formed by the one or more vertical electrodes 112 and the one or more horizontal electrodes 114 and individual memory cells including the one or more transistors 116 and the one or more capacitors 130, are located. The pad region 203, which includes the bottom regions and top regions of FIG. 2A, may be formed apart from the region where the individual cells are formed, and may include both individual pads and one or more supporters 224 for pads to connect with the first device architecture 100. In some embodiments, multiple pad regions 203 may be formed, with the array region 201 formed between, such as in the example embodiment of FIG. 2A, where the central region the array region 201, while the top and bottom regions are pad regions 203. The array region 201 may include one or more deep trench isolators (DTI) or cell deep trench isolators (CDTI) extending in the X-direction, with a closed DTI 222 between one or more open DTI 220 and the pad region 203 in the Y-direction. Each of the one or more open DTIs 220 may include a capacitor isolator 230, which extends in the Y-direction. The capacitor isolator 230 is formed between pairs of the one or more open DTIs 220 in the X-direction, and may be between a pair of closed DTIs 222 which are spaced apart in the Y-direction. In some embodiments, the one or more open DTIs 220, the closed DTIs 222, and the capacitor isolators 230 may be formed from the second dielectric material 106, while in other embodiments the first dielectric material 104 or another dielectric material may be used.

FIG. 2B depicts a perspective view of the intermediate structure 200 shown in FIG. 2A, and including an epitaxial stack 300. The view of FIG. 2B shows a partial cross-section in the array region 201 along the lines formed by a first box 205 in FIG. 2A, with an additional cross-section in the pad region 203. In the pad region 203, the epitaxial stack 300 may include an alternating structure of bulk semiconductor layers 108 between one or more liner layers 202, and may include a base liner layer 204 between the epitaxial stack 300 and the rest of the epitaxial stack 300. The base liner layer 204 may also be referred to as the first compound semiconductor layer, and the one or more liner layers 202 may be referred to as the second compound semiconductor layers. A compound semiconductor may refer to a semiconductor material formed from multiple individual semiconductors. For example, a binary semiconductor is a compound semiconductor including two semiconductor materials, such as silicon and germanium. Within the pad region 203, one or more supporters 224 may be formed from a material such as the second dielectric material 106. The one or more supporters 224 may be formed within a trench penetrating the epitaxial stack 300 and extending from the first top isolation layer 111 at least partially into the substrate 102. In some embodiments, the one or more supporters 224 may provide support for pads later formed in the pad region 203, while in other embodiments, the one or more supporters 224 may be removed prior to the formation of the first device architecture 100.

The alternating structure of the epitaxial stack 300, including one or more liner layers 202, bulk semiconductor layers 108 and the base liner layer 204, may be formed using an epitaxial process where a crystalline layer is grown on top of another crystalline layer so as to influence the crystalline orientation of the grown layer, such as chemical vapor deposition (CVD), atomic layer deposition (ALD), and physical vapor deposition (PVD). A stack of multiple layers produced this way may be referred to as an epitaxial stack or epistack. As such, in some embodiments, the crystalline orientation of the one or more liner layers 202 and the bulk semiconductor layers 108 may match the crystalline orientation of the base liner layer 204. In some embodiments, an additional seed layer may be inserted above or below the base liner layer 204 to control the crystalline orientation of the subsequent layers. The bulk semiconductor layers 108 may be formed by a bulk semiconductor material such as silicon or germanium. The one or more liner layers 202 and the base liner layer 204 may be formed from a combination of semiconductors, or compound semiconductors, for example silicon germanium (SiGe). The composition of the liner layers 202 may be the same or may vary. The bulk semiconductor layers 108 may likewise all have the same composition or may differ. The one or more liner layers 202 and the base liner layer 204 may be formed from the same combination of semiconductor materials, for example, both being made of SiGe, but may differ in one or more of concentration of semiconductor materials, additives, dopants, as well as additional properties such as thickness.

FIG. 2C depicts an enlarged perspective view of the intermediate structure 200, showing a cross-sectional view in the array region 201 as formed by the second box 207 in FIG. 2A. The epitaxial stack 300 may be modified within the array region 201, with the epitaxial stack 300 within the array region 201 being modified to provide support for later formation of elements of the individual device layers 120 such as the one or more horizontal electrodes 114, the one or more transistors 116, the one or more capacitors 130. As shown in FIG. 2C, within the array region 201, the bulk semiconductor layer 108 may be modified such that the base liner layer 204 shown in FIG. 2B is replaced with the substrate isolation layer 110. In addition, the one or more liner layers 202 and the bulk semiconductor layer 108 may be partially recessed where the intralayer dielectrics 122 are formed between thinned portions of the bulk semiconductor layers 108. The closed DTIs 222 and one or more open DTIs 220 may be formed similarly to the one or more supporters 224, and may be formed within a trench penetrating the epitaxial stack 300 and extending from the first top isolation layer 111 at least partially into the substrate 102. The closed DTIs 222 and one or more open DTIs 220 may be formed of a material such as the second dielectric material 106. As shown in FIG. 2A-2C, the closed DTIs 222 which extend in the X-direction, are formed on the opposing Y-direction ends of the array region 201, with the one or more open DTIs 220 extending in the X-direction formed between the ends of the array region 201 in the Y-direction. Between pairs of the one or more open DTIs 220 in the X-direction and the closed DTIs 222 on both ends of the array region 201 in the Y-direction, the capacitor isolator 230 may be formed extending in the Y-direction. Similarly to the DTIs, the capacitor isolator 230 may be formed within a trench penetrating the epitaxial stack 300 in the Z-direction and stretching in the Z-direction from the first top isolation layer 111 at least partially into the substrate 102, and may be formed of a material such as the second dielectric material 106. In some embodiments, the trenches forming the closed DTIs 222, the one or more open DTIs 220, the one or more supporters 224 and the capacitor isolator 230 may penetrate to the same depth in the Z-direction within the substrate 102. In other embodiments, the trenches forming the closed DTIs 222, the one or more open DTI 220, the one or more supporters 224 and the capacitor isolator 230 may penetrate in the Z-direction to differing depths within the substrate 102.

The base liner layer 204 may differ from the one or more liner layers 202 in composition, for example, having one or more of a different semiconductor concentration; a different thickness, a differing dopant concentration, or a combination thereof. In some embodiments, the base liner layer 204 may differ from the one or more liner layers 202 in terms of semiconductor concentration; for example, both the base liner layer 204 and the one or more liner layers 202 may be formed of a binary semiconductor such as silicon germanium, with the concentration of the semiconductors differing, for example, the base liner layer 204 may have a relatively high concentration of germanium such as 25% or greater, while the one or more liner layers 202 may have a relatively lower concentration of germanium such as 15% or greater, although in some embodiments, the lower concentration of germanium may be less than 15%. In some embodiments, the base liner layer 204 may differ from the one or more liner layers 202 in terms of thickness; for example, both the base liner layer 204 and the one or more liner layers 202 may be formed in the nanometer range, for example in the range between 1 and 1,000 nm. However, the base liner layer 204 may be relatively thick, for example having a thickness in the range of 50-100 nm, while the one or more liner layers 202 may be relatively thin, for example, having a thickness in the range of 1-10 nm. In some embodiments, the base liner layer 204 may differ from the one or more liner layers 202 by differing in doping concentration, for example, carbon may be used as a dopant having a relatively high concentration in the one or more liner layers 202, while having a relatively low concentration in the base liner layer 204. In some embodiments, the differences between the base liner layer 204 and the one or more liner layers 202 may provide a difference in etching rates between the base liner layer 204 and the one or more liner layers 202, such that an etch which may partially recess the one or more liner layers 202 may fully or nearly fully recess the base liner layer 204. In other embodiments, the etch response may be such that an etch which may partially recess the base liner layer 204 may fully or nearly fully recess the one or more liner layers 202, allowing a single etch process to provide multiple etch depths. For example, a fully recessed layer may be suitable for creating an isolation layer, while a partially recessed layer may be useful for defining a transistor formed using the epistack.

In view of the foregoing, differences between the base liner layer 204 and the one or more liner layers 202 may be used to form the space where intralayer dielectrics 122 and the substrate isolation layer 110 are formed, with a selective etch process applied to partially remove portions of the one or more liner layers 202, the bulk semiconductor layers 108, as well as fully or nearly fully removing the base liner layer 204. In some embodiments, the selective etching may be done using a lateral etch process.

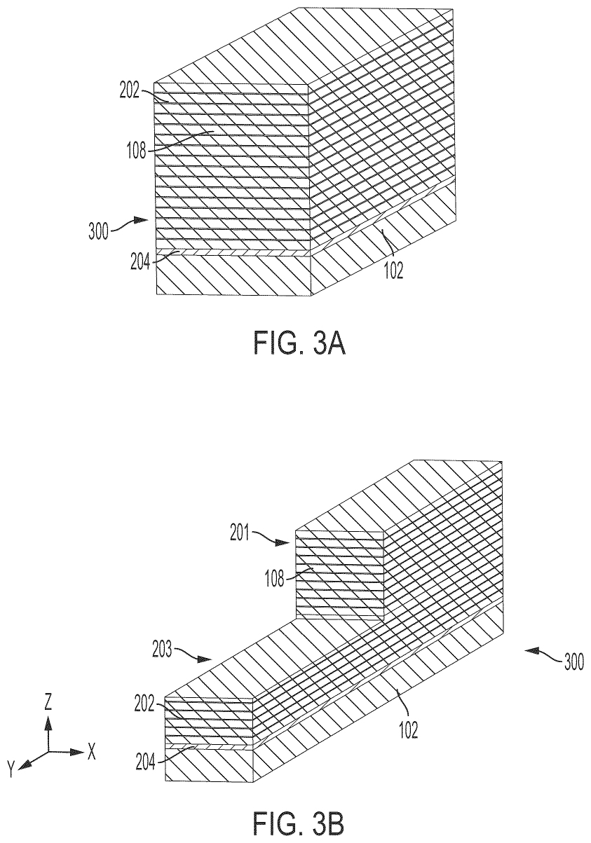

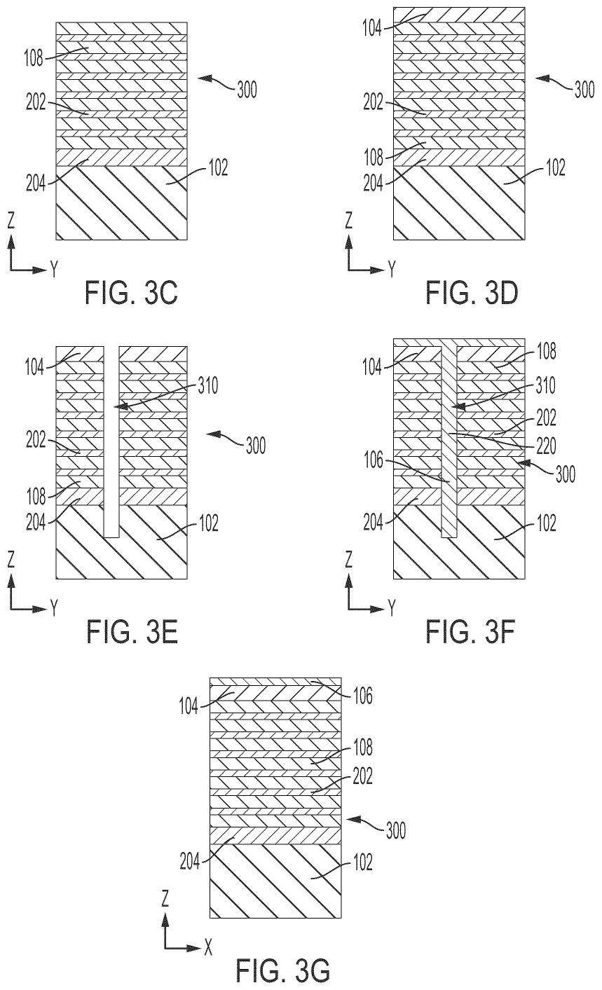

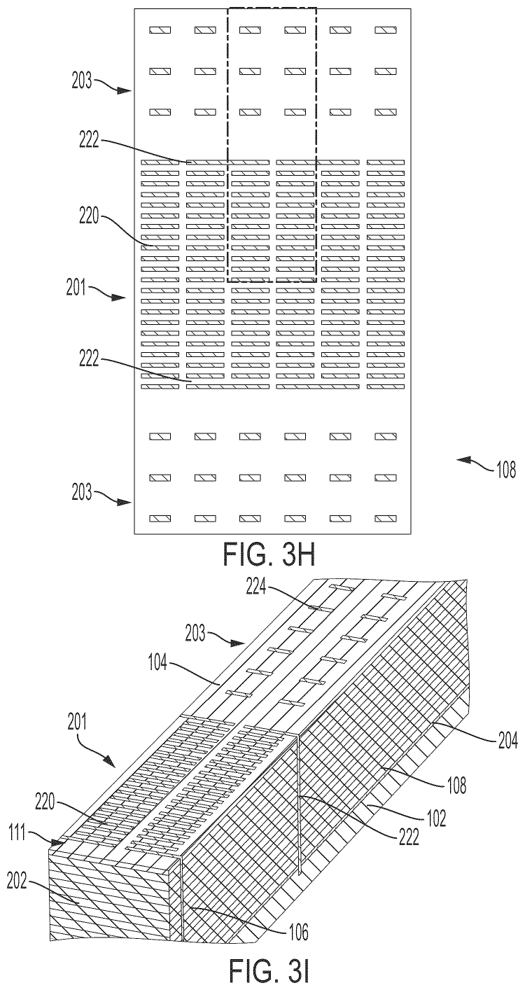

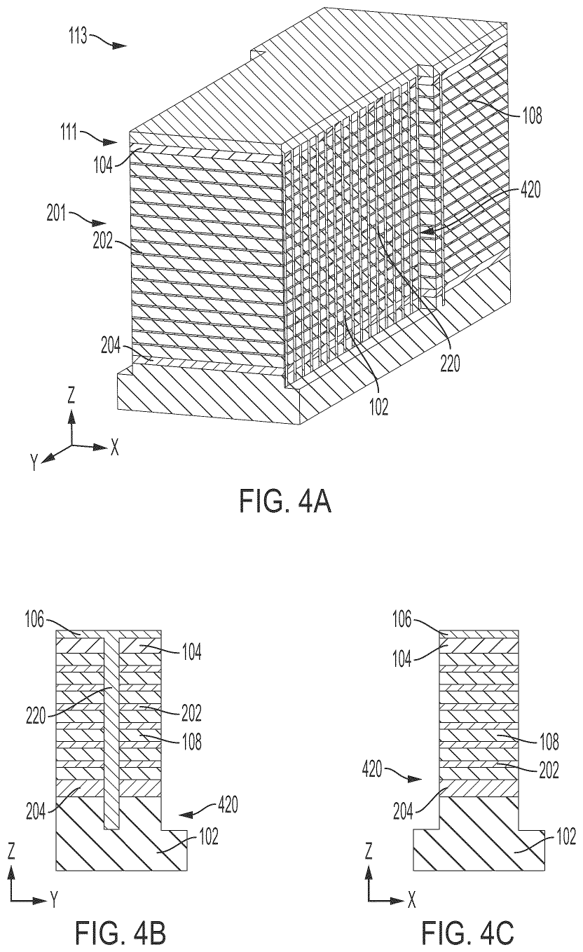

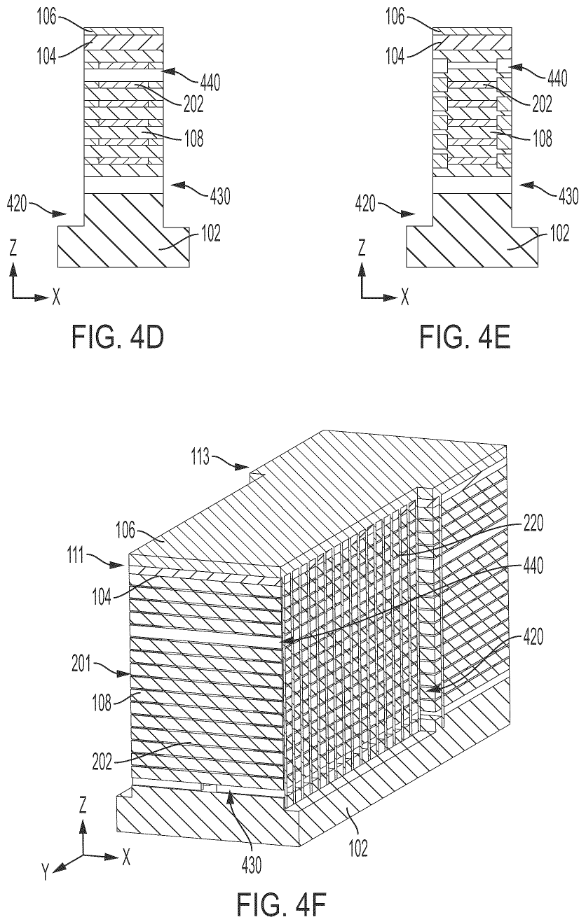

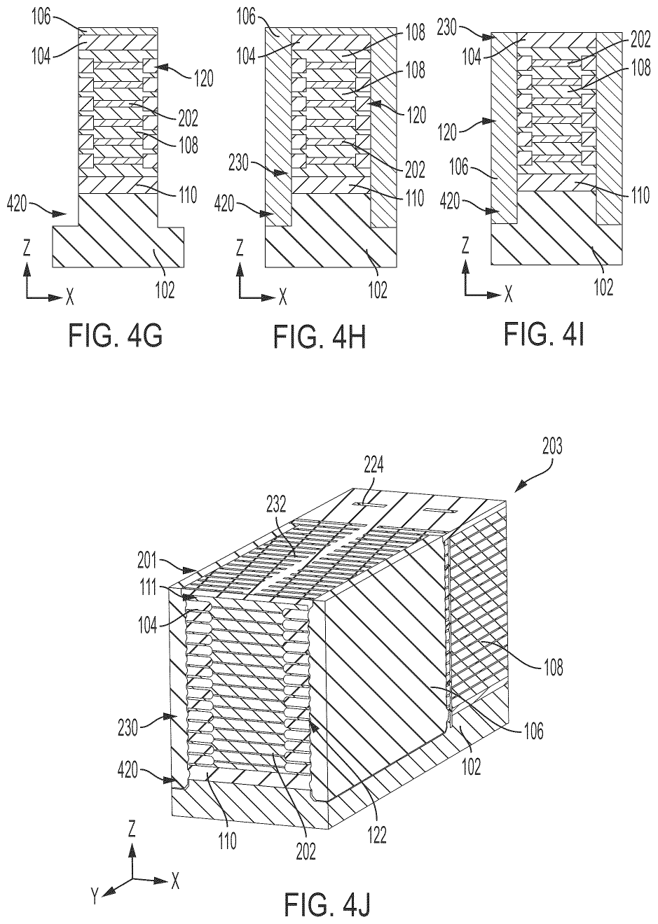

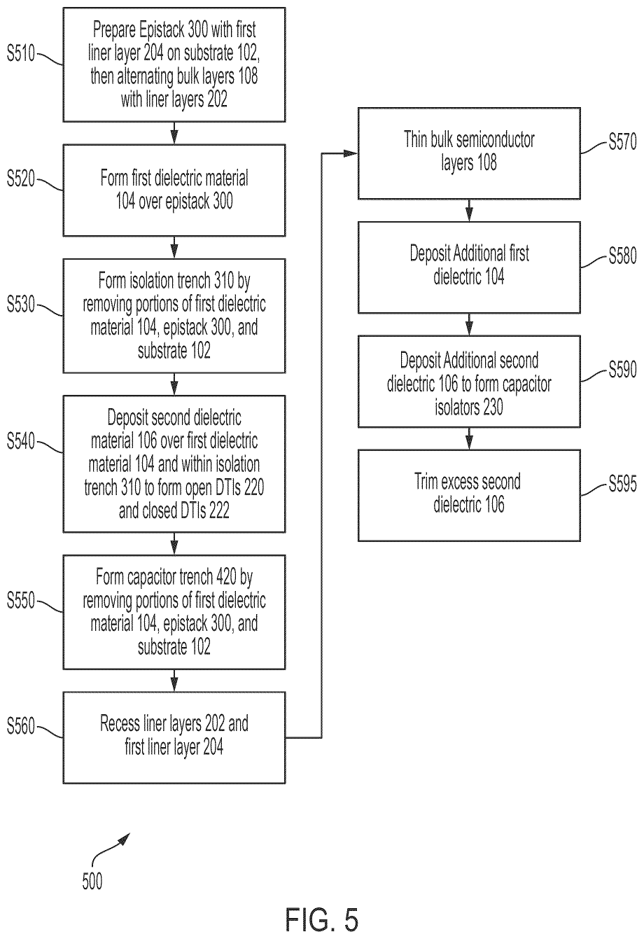

FIGS. 3A-3I and 4A-4J depict an illustrative embodiment of a process of forming a device architecture such as the first device architecture 100, or any other device architectures shown herein. FIG. 5 depicts an example embodiment of a process 500 for forming a device architecture corresponding to the illustrative embodiment of FIGS. 3A-3I and 4A-4J. The process 500 may be divided into a first set of steps corresponding with FIGS. 3A-3J involving the formation of deep trench isolation structures, with a second step of steps corresponding with FIGS. 4A-4J involving the formation of the substrate isolation layer 110, the intralayer dielectrics 122, and the capacitor isolator 230.

FIG. 3A, FIG. 3B and FIG. 3C depict S510 in the process of FIG. 5, where the epitaxial stack 300 is formed. FIG. 3A and FIG. 3B provide perspective views of the epitaxial stack in the pad region 203 and the array region 201. FIG. 3C provides a cross-sectional view in either the X-Z or Y-Z plane for the epitaxial stack 300. In some embodiments, the epitaxial stack 300 may be formed directly on the substrate 102, while in other embodiments the epitaxial stack 300 may be formed in a separate process and transferred to the substrate 102. In some embodiments, the first layer formed may be the base liner layer 204 directly on the substrate 102, while in some embodiments one or more additional layers may be formed between the base liner layer 204 and the substrate 102. For example, in some embodiments, one or more seed layers may provide a crystalline orientation for the epitaxial stack 300, while some embodiments may provide a glue layer or material matching layer to allow a better adhesion between the epitaxial stack 300 and the substrate 102, or to allow for when the epitaxial stack 300 is made in another process and transferred on to the substrate 102. In some embodiments, when the epitaxial stack 300 is formed on a separate substrate, the epitaxial stack 300 may be formed in a reverse order, with the top of the epitaxial stack 300 formed first, and the base liner layer 204 formed last.

The epitaxial stack 300 may be formed using a semiconductor manufacturing process compatible with epitaxy, such as physical vapor deposition (PVD), chemical vapor deposition (CVD) and atomic layer deposition (ALD). In some embodiments, the individual layers of the epitaxial stack 300 may be formed using the same process, while in other embodiments, multiple processes may be used. In some embodiments, the epitaxial stack 300 may be formed using a single process technique, with variations within process controls such as time, materials, and energy level to produce the base liner layer 204, the one or more liner layers 202, and the bulk semiconductor layers 108. For example, in a process such as ALD, individual layers may be grown by controlling relative amounts of silicon and germanium, with the bulk semiconductor layers 108 produced by forming silicon layers using a silicon source, while the one or more liner layers 202 may add a germanium source to form SiGe layers, with the base liner layer 204 formed differently than the rest of the one or more liner layers 202. For example, the base liner layer 204 may have a different concentration of semiconductor materials, such as a different ratio of silicon and germanium in a SiGe layer, also known as a difference in composition, as well as may have a difference in deposition time to produce a difference in thickness, and may further include a difference in dopant concentrations. The individual layers of the bulk semiconductor layers 108 may then be reproduced using the same or similar conditions for each of the bulk semiconductor layers 108. In some embodiments, differences may be introduced to the conditions for the formation of the bulk semiconductor layers 108, if desired to form additional layers having differing properties, such as thickness, dopant concentration, etc. The one or more liner layers 202 may be formed using the same or similar conditions for each of the one or more liner layers 202. In some embodiments, the formation of the epitaxial stack 300 may include three processes, a formation of the base liner layer 204, a formation of the one or more liner layers 202, and formation of the bulk semiconductor layers 108, with the steps forming the one or more liner layers 202 and the bulk semiconductor layer 108 repeated as desired after the formation of the base liner layer 204.

FIG. 3D depicts S520 in the process of FIG. 5, where the first dielectric material 104 is formed over the epitaxial stack 300. FIG. 3D provides a cross-sectional view in the Y-Z plane, where the first dielectric material 104 covers the top of the epitaxial stack 300. The first dielectric material 104 may be formed using a semiconductor process suitable for forming a dielectric, including PVD, CVD, ALD, or any other suitable semiconductor process. The first dielectric material 104 may be formed from semiconductor materials, as well as nitrides, carbides, and oxides thereof, and may consist of silicon nitride, silicon dioxide, or other similar materials such as gallium nitride, gallium oxide, and so forth, and in some embodiments may consistent of a high-k dielectric with a higher dielectric constant (κ) than silicon dioxide, and may include materials such as oxides, silicides and silicates of hafnium and zirconium, such as hafnium silicate, zirconium silicate, hafnium dioxide and zirconium dioxide.

FIG. 3E depicts S530 in the process of FIG. 5, where an isolation trench 310 is formed by removing portions of the first dielectric material 104, the epitaxial stack 300, and the substrate 102. The portions of the first dielectric material 104, the epitaxial stack 300, and the substrate 102 may be removed using any suitable semiconductor process, and may include techniques such as selective etching, including both wet-etch processes using chemicals and dry-etch processes using reactive plasma, as well as lithography, mechanical drilling or cutting, lasers, and a combination of these methods and any other suitable methods known in the art. The isolation trench 310 may then extend from the first dielectric material 104 through the epitaxial stack 300, and at least partially into the substrate 102. In some embodiments, the isolation trench 310 may be formed after a photoresist or other form of mask is prepared, so the isolation trench 310 may have a pattern, such as that shown in the example embodiment of FIG. 2A. In some embodiments with a photoresist or other form of mask, the mask may be removed after the isolation trench 310 is formed and before S540.

FIGS. 3F-3I depict S540 in the process of FIG. 5, where the second dielectric material 106 is deposited over the first dielectric material 104 and within the isolation trench 310 to form the closed DTIs 222 and one or more open DTI 220. The second dielectric material 106 may be formed using a semiconductor process suitable for forming a dielectric, including PVD, CVD, ALD, or any other suitable semiconductor process. The second dielectric material 106 may be formed from semiconductor materials, as well as nitrides, carbides, and oxides thereof, and may consist of silicon nitride, silicon dioxide, or other similar materials such as gallium nitride, gallium oxide, and so forth, and in some embodiments may consistent of a high-k dielectric with a higher dielectric constant (κ) than silicon dioxide, and may include materials such as oxides, silicides and silicates of hafnium and zirconium, such as hafnium silicate, zirconium silicate, hafnium dioxide and zirconium dioxide. In some embodiments, the materials used for the second dielectric material 106 and the first dielectric material 104 may be chosen, at least in part, to allow for selective removal of one of the dielectric materials without substantially effecting the other dielectric material. For example, dielectrics formed using carbides, nitrides, and oxides may respond differently to different etch processes, including both wet-etch and dry-etch processes. As such, in some embodiments, the second dielectric material 106 may be an oxide while the first dielectric material may be a nitride, while in other embodiments the second dielectric material 106 may be a nitride while the first dielectric material may be an oxide.

FIGS. 4A-4C depict S550 in the process of FIG. 5, where the capacitor isolation trench 420 is formed by removing portions of the first dielectric material 104, the second dielectric material 106, the epitaxial stack 300, and the substrate 102. The portions of the first dielectric material 104, the second dielectric material 106, the epitaxial stack 300, and the substrate 102 may be removed using any suitable semiconductor process, and may include techniques such as selective etching, including both wet-etch processes using chemicals and dry-etch processes using reactive plasma, as well as lithography, mechanical drilling or cutting, lasers, and a combination of these methods and any other suitable methods known in the art. The capacitor isolation trench 420 may then extend from the second dielectric material 106 and the first dielectric material 104 through the epitaxial stack 300, and at least partially into the substrate 102. In some embodiments, the capacitor isolation trench 420 may be formed after a photoresist or other form of mask is prepared, so the capacitor isolation trench 420 may have a pattern, such as that shown in the example embodiment of FIG. 2A. In some embodiments with a photoresist or other form of mask, the mask may be removed after the capacitor isolation trench 420 is formed and before S560.

FIG. 4D depicts S560 in the process of FIG. 5, where a removal step process may fully (or nearly fully) recess the base liner layer 204 to form the first opening 430 and partially recess the one or more liner layers 202 to form one or more second openings 440 and. The removal of the one or more liner layers 202 and the base liner layer 204 may be performed using any suitable semiconductor process, and may include techniques such as selective etching, including both wet-etch processes using chemicals and dry-etch processes using reactive plasma, as well as lithography, mechanical drilling or cutting, lasers, and a combination of these methods and any other suitable methods known in the art. The removal of the one or more liner layers 202 may be a partial removal, and may for example, be formed to a depth of around 200 nm, although in some embodiments, the depth may be greater than 200 nm, for example in the range of 200 nm-1000 nm, and in other embodiments the depth may be less than 200 nm, for example in the range of 1 nm -200 nm. Removal of the base liner layer 204 to form the first opening 430 may be partial or complete. The removal of the base liner layer 204 and the one or more liner layers 202 may be performed within the same process, with the physical differences between the base liner layer 204 and the one or more liner layers 202 allowing for a difference in the rate of removal, such that complete removal of the base liner layer 204 may be performed with only partial recession of the one or more liner layers 202. In some embodiments, the removal may be performed using a selective etch process.

FIGS. 4E and 4F depict S570 in the process of FIG. 5, where the bulk semiconductor layers 108 may be thinned. The thinning of the bulk semiconductor layers 108 may be performed using any suitable semiconductor process, and may include techniques such as selective etching, including both wet-etch processes using chemicals and dry-etch processes using reactive plasma, as well as lithography, mechanical drilling or cutting, lasers, and a combination of these methods and any other suitable methods known in the art. The thinning may be performed using a selective technique such that portions of the bulk semiconductor layers 108 may be removed, but portions made from the first dielectric material 104, the second dielectric material 106 and the one or more liner layers 202 may be unaffected. In some embodiments, the thinning may be performed using a lateral selective etch process. As a result of the thinning, the first opening 430 and the one or more second openings 440 may be expanded as the bulk semiconductor layers 108 are thinned. The bulk semiconductor layers 108 may be thinned about 60 nm, from a thickness of about 70 nm to a thickness of about 10 nm, although the amount of thinning may be larger or smaller.

FIG. 4G depicts S580 in the process of FIG. 5, where an additional amount of the first dielectric material 104 is deposited to form the capacitor isolator 230. The first dielectric material 104 may be formed using a semiconductor process suitable for forming a dielectric, including PVD, CVD, ALD, or any other suitable semiconductor process. The first dielectric material 104 may be formed from semiconductor materials, as well as nitrides, carbides, and oxides thereof, and may consist of silicon nitride, silicon dioxide, or other similar materials such as gallium nitride, gallium oxide, and so forth, and in some embodiments may consistent of a high-k dielectric with a higher dielectric constant (κ) than silicon dioxide, and may include materials such as oxides, silicides and silicates of hafnium and zirconium, such as hafnium silicate, zirconium silicate, hafnium dioxide and zirconium dioxide. The additional deposition of first dielectric material 104 may be performed using a process allowing lateral deposition, for example, ALD. In some embodiments, the formation of the additional portions of the first dielectric material 104 may be followed by one or more additional steps to remove any excess portions of the first dielectric material 104, such as a planarization step, selective etching, and so forth.

FIG. 4H depicts S590 in the process of FIG. 5, where an additional amount of the second dielectric material 106 is deposited. The second dielectric material 106 may be formed using a semiconductor process suitable for forming a dielectric, including PVD, CVD, ALD, or any other suitable semiconductor process. The second dielectric material 106 may be formed from semiconductor materials, as well as nitrides, carbides, and oxides thereof, and may consist of silicon nitride, silicon dioxide, or other similar materials such as gallium nitride, gallium oxide, and so forth, and in some embodiments may consistent of a high-k dielectric with a higher dielectric constant (κ) than silicon dioxide, and may include materials such as oxides, silicides and silicates of hafnium and zirconium, such as hafnium silicate, zirconium silicate, hafnium dioxide and zirconium dioxide. In some embodiments, the second dielectric material 106 may be deposited such that an additional layer of the second dielectric material 106 is formed on the epitaxial stack 300.

FIGS. 4I and 4J depict S595 in the process of FIG. 5, where excess amounts of the second dielectric material 106 may be trimmed. FIG. 4I provides a cross-sectional view, while FIG. 4J provides a perspective view. The trim may be performed using any suitable semiconductor process, and may include techniques such as planarization, chemical-mechanical polishing (CMP), selective etching, including both wet-etch processes using chemicals and dry-etch processes using reactive plasma, as well as lithography, mechanical drilling or cutting, lasers, and a combination of these methods and any other suitable methods known in the art. In some embodiments, the trim may expose the first dielectric material 104 on the top of the epitaxial stack 300, while in other embodiments, the trim may leave a portion of the second dielectric material 106 on the first dielectric material 104, and in other embodiments, the trim may remove some or all of the first dielectric material 104 in addition to the second dielectric material 106 on top of the epitaxial stack 300.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific example teachings discussed above, but is instead defined by the following claims.

What is claimed is:

1. A device comprising:
a substrate;
a first dielectric layer located on top of the substrate;
a second dielectric layer located on top of the first dielectric layer;
a first epitaxial semiconductor layer, arranged between the first dielectric layer and the second dielectric layer;
a second epitaxial semiconductor layer on top of the second dielectric layer; and
a third dielectric layer, the third dielectric layer contacting the first dielectric layer, the second dielectric layer, the first epitaxial semiconductor layer, and the second epitaxial semiconductor layer.

2. The device of claim 1, wherein the first dielectric layer and the second dielectric layer comprise a nitride.

3. The device of claim 1, wherein the third dielectric layer contacts the substrate and extends in a direction orthogonal to the substrate.

4. The device of claim 1, wherein
the first epitaxial semiconductor layer has a thickness of 5-20 nm, and
the second epitaxial semiconductor layer has a thickness of 5-20 nm.

5. The device of claim 1, wherein the third dielectric layer comprises an oxide.

6. The device of claim 1, wherein the first dielectric layer extends in a direction parallel to the substrate, the first dielectric layer extending between the substrate and the first epitaxial semiconductor layer across the width of the first epitaxial semiconductor layer.

7. The device of claim 1, wherein the first epitaxial semiconductor layer, the second epitaxial semiconductor layer, and the substrate share a common crystalline orientation.

8. A system comprising:
a substrate;
a first dielectric layer contacting the substrate; and
a vertical electrode extending in a direction orthogonal from the substrate, the first dielectric layer arranged between the substrate and the vertical electrode;
a first epitaxial semiconductor layer extending in a direction parallel to the substrate, the first epitaxial semiconductor layer conductively coupled to the vertical electrode;
a second dielectric layer arranged on top of the first epitaxial semiconductor layer; and
a second epitaxial semiconductor layer arranged on top of the second dielectric layer,
wherein the first dielectric layer isolates the substrate from the vertical electrode.

9. The system of claim 8, further comprising a third dielectric layer contacting the substrate and the first dielectric layer, the third dielectric layer extending in a direction parallel to the vertical electrode,
wherein the first epitaxial semiconductor layer is arranged between the third dielectric layer and the vertical electrode, and
wherein the first dielectric layer is a nitride and the third dielectric layer is an oxide.

10. The system of claim 8, wherein the first epitaxial semiconductor layer, the second epitaxial semiconductor layer, and the substrate share a common crystalline orientation.

11. The system of claim 8, wherein the second dielectric layer isolates the first epitaxial semiconductor layer from the second epitaxial semiconductor layer, and wherein the second epitaxial semiconductor layer is conductively coupled to the vertical electrode.

12. The system of claim 8, wherein the first dielectric layer and the second dielectric layer are comprised of the same dielectric material.

13. The system of claim 8, wherein the first dielectric layer extends in a direction parallel to the substrate beyond the second dielectric layer.

14. A method comprising:
forming a stack on a substrate including a first epitaxial semiconductor layer on the substrate, and a second epitaxial semiconductor layer on the first epitaxial semiconductor layer;
forming a first recess within the first epitaxial semiconductor layer;
forming a second recess within the second epitaxial semiconductor layer
depositing a first dielectric material to fill the first recess to form a first dielectric layer, and depositing the first dielectric to fill the second recess to form a second dielectric layer; and
depositing a second dielectric material, the second dielectric material extending in a direction orthogonal to the substrate.

15. The method of claim 14, wherein the first dielectric layer extends fully between the first epitaxial semiconductor layer and the substrate.

16. The method of claim 14, wherein the first epitaxial semiconductor layer and the second epitaxial semiconductor layer are formed of epitaxial silicon sharing the same crystalline orientation as the substrate.

17. The method of claim 14, wherein the second dielectric layer extends partially between the first epitaxial semiconductor layer and the second epitaxial semiconductor layer.

18. The method of claim 14, wherein
the first dielectric material is a nitride, and
the second dielectric material is an oxide.

19. The method of claim 14, wherein the first recess and the second recess are formed in a direction parallel to the substrate.

20. The method of claim 14, wherein the second dielectric material contacts the first epitaxial semiconductor layer and the second epitaxial semiconductor layer.
